(19) United States
(12) Patent Application Publication
(10) Pub. No.: US 2026/0309784 A1
(43) Pub. Date: Oct. 8, 2026

(54) BATTERY STATES CO-ESTIMATION TECHNIQUE USING DUAL SQUARE ROOT UNSCENTED KALMAN FILTER

(71) Applicant: SMARTKOSH TECHNOLOGIES PRIVATE LIMITED, Hyderabad (IN)

(72) Inventors: Amit ACHARYYA, Hyderabad (IN); Souris SAHU, Hyderabad (IN); Rashi DUTT, Hyderabad (IN)

(73) Assignee: SMARTKOSH TECHNOLOGIES PRIVATE LIMITED, Hyderabad (IN)

(21) Appl. No.: 19/485,204

(22) PCT Filed: May 17, 2025
(86) PCT No.: PCT/IN2024/050577

§ 371 Date: Nov. 17, 2025

(30) Foreign Application Priority Data
May 18, 2023 (IN) 202341034752

(51) Int. Cl. G01R 31/367; G01R 31/3842; G01R 31/389; G01R 31/392

(52) U.S. Cl. CPC G01R 31/367; G01R 31/3842; G01R 31/389; G01R 31/392

(57) ABSTRACT

The present invention discloses a method of co-estimating battery state using D-SRUKF. The method includes creating a 2-RC circuit battery model equivalent to electrical circuit of a battery. Further, the method includes performing incremental open circuit voltage (OCV) test to extract a plurality of 2-RC model parameters. The parameters include internal resistance, temperature and the open circuit voltage (OCV). The method further includes estimating a State Of Charge (SOC) of the battery using the D-SRUKF based on a co-estimation technique. Further, the method includes estimating a State of Health (SOH) of the battery based on the SOC and the OCV of the 2-RC circuit battery model. The method further includes estimating a State Of Power (SOP) of the battery based on maximum deliverable power, maximum allowable voltage, the internal resistance, and the OCV.

### FIELD OF INVENTION

The present invention relates generally to Battery Management System (BMS) and more specifically it relates to a highly accurate, robust and real-time battery state monitoring technology for Li-ion batteries. A Dual Square Root Unscented Kalman Filter (D-SRUKF) based online battery state monitoring is designed to offer higher accuracy and improved stability compared to the existing state-of-the-art battery state estimation and monitoring techniques.

### BACKGROUND OF THE INVENTION

Lithium-ion batteries have emerged as a significant energy source in several critical and emerging applications such as electric transportation, power grids, aerospace and defence applications, medical devices, and consumer electronics to name a few. This is owing to high energy density, low self-discharge rate, and higher power-delivering capability. Due to their importance in such critical applications, monitoring the batteries at each stage of the operation is essential for ensuring safety during operation and improving the life cycle. Furthermore, the capacity fading with continued operation over time leads to the degradation of the batteries and can even make the energy storage system accident-prone. Consequently, most battery packs are designed with a Battery Management System (BMS) to extract optimal performance and maintain operational safety. A critical function of the BMS is to estimate and predict the battery states such as State-of-Charge (SOC), State-of-Health (SOH), and State-of-Power (SOP) for real-time monitoring of the battery-powered application.

Most battery state estimation techniques perform the estimation of states individually. Primarily, cell degradation models are developed for SOH estimation. However, the critical battery states (such as SOC, SOH, and SOP) are highly interdependent on each other. For instance, essential parameters for SOC estimation, such as resistance and internal capacity change with the aging of the battery which reduces the battery's power-delivering capability over time. Moreover, separate estimations of the states may also lead to inaccurate estimation results without considering the effect of one over another. Recently, simultaneous battery state-parameter estimation techniques are gaining attraction, which improves the performance of the BMS state estimation by considering the batteries' aging. Joint estimation technique for SOC and SOH. An EKF-based co-estimation is proposed to estimate SOC and State-of-Function (SOF) together. The Recursive Least Square (RLS) algorithm is used with a forgetting factor to identify online OCV through parameter estimation and internal resistance to update capacity further. However, this co-estimation technique utilizes separate filters to estimate SOC and SOH.

SOC is the ratio of the available charge to the maximum charge capacity of a battery. Several techniques for SOC estimation currently exist. On the other hand, SOH is a measure of the battery's age, estimated either by quantifying the capacity loss or detecting the increase in internal resistance. Finally, SOP estimation is a function of the current limit, voltage limit, and SOC. A technique to estimate SOP is reported where internal parameters such as resistances are updated using the dynamic system model and SOC.

The most widely used technique for battery states monitoring is the book-keeping method which exploits the relationship between State-of-Charge (SOC) the battery characteristics such as the Open-Circuit volt-age (OCV) and generates a look-up table. SOC estimation is performed by measuring the OCV value and finding the corresponding SOC value. This technique is not suitable for dynamic power applications as well as older batteries since it does not consider the parameter degradation due to aging. Also, for several emerging battery chemistries such as LFP cells, the SOC-OCV curve is flat over a wide region, indicating the non-linear relation between SOC-OCV. Therefore, the technique leads to unacceptable inaccuracies in the estimation. Another state-of-the-art technique is the Coulomb Counting method, where given an initial value, SOC (to), the time integral of the terminal current can be taken as an indicator for the battery's available charge. However, the Coulomb counting method is prone to sensor offset errors and does not consider parameter variations due to aging and continued operation. Therefore, these widely implemented techniques are not suitable for aged batteries and may compromise the safety of the system.

Recently, model-based SOC estimation using Kalman Filter (KF) has been gaining popularity due to its robustness, and high accuracy for online states estimation. However, the widely used formulation of KF, i.e., the Extended Kalman Filter (EKF), fails to estimate accurately over a long run due to the unpredictable characteristics of measurement noise varying with the aging of battery and sensing instruments. Dual EKF (D-EKF) and Dual Unscented Kalman Filter (D-UKF) based state-parameter estimation techniques have been presented, however, the techniques provide inaccurate results due to instability in the system. The instability in the KF estimators such as D-EKF and D-UKF occur on account of the error covariance matrix becoming ill-condition which leads to divergence of the estimated values. The square root formulation of Kalman Filter is known to provide highly stable and accurate since the square root form of the covariance matrix is always positive semi-definite.

As the battery states such as SOC, SOH, and SOP are highly interdependent on each other separate SOC estimation reduces the accuracy of estimation. Dual estimation of states and parameters improves accuracy and stability. Co-estimation of states improves the numerical accuracy over the entire lifetime of the battery-powered operation. An EKF-based co-estimation is proposed to estimate SOC and State-of-Function (SOF) together where instead of dual estimation of state and parameter the Recursive Least Square (RLS) algorithm is used with a forgetting factor to the estimation of parameter and internal resistance to update capacity further. The disadvantage of this method is that EKF is highly prone to linearization and truncation errors and leads to instability and reduced accuracy of the system. Also, it requires derivatives computation (Jacobian or Hessnian) in the critical path, resulting in slower execution and high resource utilization.

A plurality of references for the techniques and method provided above is listed below:
[1] J. Schmalstieg, S. Ka″bitz, M. Ecker, and D. U. Sauer, “A holistic aging model for li (nimnco) o2 based 18650 lithium-ion batteries,” Journal of Power Sources, vol. 257, pp. 325-334, 2014.
[2] G.-w. You, S. Park, and D. Oh, “Real-time state-of-health estimation for electric vehicle batteries: A data-driven approach,” Applied energy, vol. 176, pp. 92-103, 2016.
[3] Y. Zou, X. Hu, H. Ma, and S. E. Li, “Combined state of charge and state of health estimation over lithium-ion battery cell cycle lifespan for electric vehicles,” Journal of Power Sources, vol. 273, pp. 793-803, 2015.
[4] G. Dong, J. Wei, and Z. Chen, “Kalman filter for onboard state of charge estimation and peak power capability analysis of lithium-ion batteries,” Journal of Power Sources, vol. 328, pp. 615-626, 2016.
[5] S. Schwunk, N. Armbruster, S. Straub, J. Kehl, and M. Vetter, “Particle filter for state of charge and state of health estimation for lithium-iron phosphate batteries,” Journal of Power Sources, vol. 239, pp. 705-710, 2013.
[6] Y. Zou, X. Hu, H. Ma, and S. E. Li, “Combined state of charge and state of health estimation over lithium-ion battery cell cycle lifespan for electric vehicles,” Journal of Power Sources, vol. 273, pp. 793-803, 2015.
[7] H. Rahimi-Eichi and M.-Y. Chow, “Adaptive online battery parameters/soc/capacity co-estimation,” in
[8] 2013 IEEE Transportation Electrification Conference and Expo (ITEC), pp. 1-6, IEEE, 2013.
[9] P. Shen, M. Ouyang, L. Lu, J. Li, and X. Feng, “The co-estimation of state of charge, state of health, and state of function for lithium-ion batteries in electric vehicles,” IEEE Transactions on vehicular technology, vol. 67, no. 1, pp. 92-103, 2017.
[10] R. Van Der Merwe and E. A. Wan, “The square-root unscented kalman filter for state and parameter-estimation,” in 2001 IEEE international conference on acoustics, speech, and signal processing. Proceed-ings (Cat. No. 01CH37221), vol. 6, pp. 3461-3464, IEEE, 2001.
[11] P. Kaminski, A. Bryson, and S. Schmidt, “Discrete square root filtering: A survey of current techniques,”
[12] IEEE Transactions on automatic control, vol. 16, no. 6, pp. 727-736, 1971.
[13] R. Dutt, M. Chodisetti, and A. Acharyya, “Real-time and accurate state-of-charge estimation methodology using dual square root unscented kalman filter,” in 2020 IEEE International Symposium on Circuits and Systems (ISCAS), pp. 1-5, IEEE, 2020.
[14] K. W. E. Cheng, B. P. Divakar, H. Wu, K. Ding, and H. F. Ho, “Battery-management system (bms) and soc development for electrical vehicles,” IEEE Transactions on Vehicular Technology, vol. 60, no. 1, pp. 76-88, 2011.
[15] K. Kutluay, Y. Cadirci, Y. S. Ozkazanc, and I. Cadirci, “A new online state-of-charge estimation and monitoring system for sealed lead-acid batteries in telecommunication power supplies,” IEEE Transactions on Industrial Electronics, vol. 52, no. 5, pp. 1315-1327, 2005.
[16] W. Guoliang, L. Rengui, Z. Chunbo, and C. Chan, “State of charge estimation for nimh battery based on electromotive force method,” in 2008 IEEE Vehicle Power and Propulsion Conference, pp. 1-5, IEEE, 2008.
[17] W. He, N. Williard, C. Chen, and M. Pecht, “State of charge estimation for li-ion batteries using neural net-work modeling and unscented kalman filter-based error cancellation,” International Journal of Electrical Power & Energy Systems, vol. 62, pp. 783-791, 2014.
[18] X. Wu, W. Shi, and J. Du, “Multi-objective optimal charging method for lithium-ion batteries,” Energies, vol. 10, no. 9, p. 1271, 2017.
[19] S. Nejad, “Adaptive techniques for estimation and online monitoring of battery energy storage devices,” in PhD diss., University of Sheffield,), 2016.
[20] G. L. Plett, “Extended kalman filtering for battery management systems of lipb-based hev battery packs: Part 1. background,” Journal of Power sources, vol. 134, no. 2, pp. 252-261, 2004.
[21] H. He, R. Xiong, and J. Peng, “Real-time estimation of battery state-of-charge with unscented kalman filter and rtos ucos-ii platform,” Applied energy, vol. 162, pp. 1410-1418, 2016.
[22] H. Guo, Z. Wang, Y. Li, D. Wang, and G. Wang, “State of charge and parameters estimation for lithium-ion battery using dual adaptive unscented kalman filter,” in 2017 29th Chinese Control And Decision Conference (CCDC), pp. 4962-4966, IEEE, 2017.
[23] S. Ciolino, M. Ghavami, and H. Aghvami, “On the use of wavelet packets in ultra wideband pulse shape modulation systems,” IEICE Transactions on Fundamentals of Electronics, Communications and Com-puter Sciences, vol. 88, no. 9, pp. 2310-2317, 2005.
[24] N. Otero, H. Rahimi-Eichi, J. J. Rodriguez-Andina, and M.-Y. Chow, “Fpga implementation of an ob-server for state of charge estimation in lithium-polymer batteries,” in 2014 International Conference on Mechatronics and Control (ICMC), pp. 1646-1651, IEEE, 2014.
[25] C.-Q. Du, J.-B. Shao, D.-M. Wu, Z. Ren, Z.-Y. Wu, and W.-Q. Ren, “Research on co-estimation algorithm of soc and soh for lithium-ion batteries in electric vehicles,” Electronics, vol. 11, no. 2, p. 181, 2022.
[26] Y. Gong, Y. Yu, K. Huang, J. Hu, and C. Li, “Evaluation of lithium-ion batteries through the simultane-ous consideration of environmental, economic and electrochemical performance indicators,” Journal of Cleaner Production, vol. 170, pp. 915-923, 2018.
[27] X. Li, L. Zhang, Z. Wang, and P. Dong, “Remaining useful life prediction for lithium-ion batteries based on a hybrid model combining the long short-term memory and elman neural networks,” Journal of Energy Storage, vol. 21, pp. 510-518, 2019.

Therefore, a method of co-estimating battery state is required to overcome the above challenges.

### OBJECTS OF THE INVENTION

A general object of the invention is to estimate the battery states such as SOC, SOH, and SOP in real-time with high accuracy.

Another object of the invention is to achieve higher stability of estimation for critical battery-based applications.

Another object of the invention is to estimate the states accurately over a long period of operation considering the effects of aging on the battery.

Another object of the invention is to achieve all of the above objects without increasing the computational complexity of the system.

### SUMMARY OF THE INVENTION

In a preferred embodiment, the present invention provides a method of co-estimating battery state using a D-SRUKF. The method includes creating a 2-RC circuit battery model equivalent to electrical circuit of a battery. Further, the method includes performing incremental open circuit voltage (OCV) test to extract a plurality of 2-RC model parameters. The parameters include internal resistance, temperature and the open circuit voltage (OCV). The method further includes estimating a State Of Charge (SOC) of the battery using the D-SRUKF based on a co-estimation technique. Further, the method includes estimating a State of Health (SOH) of the battery based on the SOC and the OCV of the 2-RC circuit battery model. The method further includes estimating a State Of Power (SOP) of the battery based on maximum deliverable power, maximum allowable voltage, the internal resistance, and the OCV.

In an aspect, the 2-RC circuit battery model comprises two non-observable states comprising State of Charge (SOC) and Voltage of the 2-RC circuit battery model (VRC).

In an aspect, the co-estimation technique use interdependence among battery states, and SOH of the battery is accounted for estimating SOC of the battery.

In another aspect, the maximum deliverable power is computed based on maximum charging current and maximum discharging current.

In another aspect, the maximum error in SOC estimation is 0.5% at 100%-90% SOC range, and the error in SOC estimation is less than 0.4% at 90%-0% SOC range.

In another aspect, the SOH is estimated for each charging and discharging cycle of the battery.

In another aspect, the D-SRUKF have complexity of o(L²) for state parameter estimation.

In an aspect, the D-SEUKF uses an observational model and a process model to describe a discrete time-invariant system.

In an aspect, the SOH is estimated using

$${Q}_{n} = \frac{Δ Ah}{Δ SOC} = \frac{{\int }_{{t}_{b}}^{{t}_{a}} idt}{SOC {(}_{{t}_{a}} ) - SOC {(}_{{t}_{b}} )} and {SOH}_{n} = \frac{{Q}_{n}}{{Q}_{n o m}} \times 100 .$$

In another aspect, the error in SOH estimation is less than 0.5%.

### BRIEF DESCRIPTION OF THE DRAWINGS

The accompanying drawings constitute a part of the description and are used to provide further understanding of the present invention. Such accompanying drawings illustrate the embodiments of the present invention which are used to describe the principles of the present invention. The embodiments are illustrated by way of example and not by way of limitation in the figures of the accompanying drawings in which like references indicate similar elements. It should be noted that references to “an” or “one” embodiment in this invention are not necessarily made to the same embodiment, and they mean at least one. In the accompanying drawings:

FIG. 1 illustrates a block diagram of a system for co-estimating battery states, in accordance with an embodiment of the present invention;

FIG. 2 illustrates Dynamic Stress Test (DST) current profile and voltage profile, in accordance with an embodiment of the present invention;

FIG. 3 illustrates a comparison of State of Charge (SOC) of a battery between different methodologies, in accordance with an embodiment of the present invention;

FIG. 4 illustrates error analysis for different SOC ranges, in accordance with an embodiment of the present invention;

FIG. 5 illustrates a comparison of State of Health (SOH) of the battery between different methodologies, in accordance with an embodiment of the present invention; and

FIG. 6A illustrates a comparison of internal resistance and FIG. 6B illustrates a comparison of maximum available power, in accordance with an embodiment of the present invention.

A more complete understanding of the present invention and its embodiments thereof may be acquired by referring to the following description and the accompanying drawings.

### DETAILED DESCRIPTION OF THE INVENTION

The detailed description set forth below in connection with the appended drawings is intended as a description of various embodiments of the present invention and is not intended to represent the only embodiments in which the present invention may be practiced. Each embodiment described in this invention is provided merely as an example or illustration of the present invention, and should not necessarily be construed as preferred or advantageous over other embodiments. The detailed description includes specific details for the purpose of providing a thorough understanding of the present invention. However, it will be apparent to those skilled in the art that the present invention may be practiced without these specific details.

As used herein, the term “comprising” means including but not limited to and should be interpreted in the manner it is typically used in the patent context. Use of broader terms such as comprises, includes, and having should be understood to provide support for narrower terms such as consisting of, consisting essentially of, and comprised substantially of.

The phrases “in one embodiment,” “according to one embodiment,” “in some embodiments,” and the like generally mean that the particular feature, structure, or characteristic following the phrase may be included in at least one embodiment of the present disclosure, and may be included in more than one embodiment of the present disclosure (importantly, such phrases do not necessarily refer to the same embodiment).

The word “example” or “exemplary” is used herein to mean “serving as an example, instance, or illustration.” Any implementation described herein as “exemplary” is not necessarily to be construed as preferred or advantageous over other implementations.

Approximating language, as used herein throughout the specification and claims, may be applied to modify any quantitative representation that could permissibly vary without resulting in a change in the basic function to which it is related. Accordingly, a value modified by a term or terms, such as “less than,” “approximately” etc. is not limited to the precise value specified. In some instances, the approximating language may correspond to the precision of an instrument for measuring the value.

This invention proposes a model-based co-estimation technique for SOC, SOH, and SOP estimation using a dual state-parameter estimation approach. A Dual Square Root Unscented Kalman Filter (D-SRUKF) estimator increases the numerical accuracy of the nonlinear system and outperforms D-EKF estimation. D-SRUKF provided improved performance compared to D-UKF in terms of enhanced stability and reduced computational complexity. Battery SOC and parameter estimation based on D-SRUKF has been found to be highly accurate and stable. This technique considers the internal parameter changes of the battery with continued usage and, hence, improves the accuracy and reliability of SOC estimation.

A on co-estimation and dual estimation of battery states. However, Dual estimation-based co-estimation has not been used previously for battery state estimation. The novelty of this invention lies in the fact that the estimation of several interdependent states using a dual estimator with higher accuracy and stability contributes to cumulative battery monitoring technology without adding to the computational complexity of the system.

Therefore, D-SRUKF based novel battery states co-estimation scheme predicts an accurate SOC along with SOH and SOP for aged batteries. The invented technique simplifies SOC, SOH, and SOP estimation using only a single D-SRUKF estimator compared to separate filters as presented in the EKF-RLS scheme. The D-SRUKF computational blocks can be reused for state and parameter estimation.

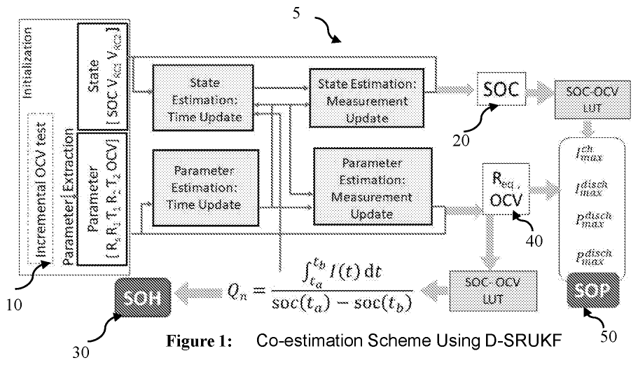

Referring now to FIG. 1, illustrates a block diagram of a system (5) for co-estimating battery states, in accordance with an embodiment of the present invention. For online estimation of non-observable battery states such as SOC, SOH, and SOF, the electrical equivalent 2-RC circuit battery model is chosen. The 2-RC model with two non-observable states (SOC and VRC) is proven to be an optimized model with improved accuracy.

The co-estimation technique exploits the interdependence among battery states. The impact of battery aging (described by SOH) on SOC is considered for estimation. The underlying principle for the battery states co-estimation includes incremental OCV test (10) to determine the relationship between OCV and SOC. The 2-RC network model, which has the non-observable states SOC (20), V_{RC1}, and V_{RC2}, is used to identify the RC model parameters because it provides greater accuracy and dynamic performance. Further, SOH estimation (30) updates the battery capacity, and SOC is the estimation of available capacity out of total charge capacity. Both are estimated using the highly accurate and stable D-SRUKF estimator. Further, estimated parameters such as OCV, internal resistance (R_{eq}) (40) and states such as SOC, the voltage of lumped RC model (V_{RC1} and V_{RC2}) are used for estimation of SOP (50).

The D-SRUKF requires an observation model O and process model P to describe a discrete time-invariant system as shown in equations 1-3:

$${x}_{t + 1} = P ( {x}_{t} , {θ}_{t} , {u}_{t} ) + {ω}_{t} , {ω}_{t} = N \{ 0 , {R}^{n} \} \qquad ( 1 )$$

$${z}_{t} = O ( {x}_{t} , {θ}_{t} , {u}_{t} ) + {v}_{t} , {v}_{k} = N \{ 0 , {R}^{v} \} \qquad ( 2 )$$

$${x}_{t} = [ {SOC}_{t} {V}_{RC 1 t} {V}_{RC 1 t} ] \qquad ( 3 )$$

In equations 1-3, xₜ is the battery states, zₜ is the observation vector, and uₜ is control input. ωₜ is the process noise, and vₜ is measurement noise. ωₜ has zero mean and Rⁿ covariance. vₜ has zero mean and R^{v} covariance. The state-space model formulation for the 2-RC battery model to estimate the SOC is presented in equation 3.

$$P ( . ) = [ \begin{matrix}{x}_{1} \\ {x}_{2} \\ {x}_{3}\end{matrix} ] = [ \begin{matrix}{SOC}_{t + 1} \\ {V}_{{RC}_{{1}_{t + 1}}} \\ {V}_{{RC}_{{2}_{t + 1}}}\end{matrix} ] = [ \begin{matrix}1 & 0 & 0 \\ 0 & {e}^{\frac{- Δ t}{{R}_{1} {C}_{1}}} & 0 \\ 0 & 0 & {e}^{\frac{- Δ t}{{R}_{2} {C}_{2}}}\end{matrix} ] [ \begin{matrix}{SOC}_{t} \\ {V}_{{RC}_{{1}_{t}}} \\ {V}_{{RC}_{{2}_{t}}}\end{matrix} ] + [ \begin{matrix}\frac{η}{{SOH}_{n} * {Q}_{nom}} {I}_{t} & 0 & 0 \\ 0 & {R}_{1} ( 1 - {e}^{\frac{- Δ t}{{R}_{1} {C}_{1}}} ) & 0 \\ 0 & 0 & {R}_{2} ( 1 - {e}^{\frac{- Δ t}{{R}_{2} {C}_{2}}} )\end{matrix} ] {I}_{t} \qquad ( 4 )$$

In equation 4, SOC and the voltages across 2-RC network V_{RC1}, and V_{RC2}, changes over time step t to t+1. Iₜ is the terminal current. The nominal capacity is Qₙₒₘ in Ah. η is the coulombic efficiency of the battery. Equation 3 provides the integral of current over time steps to calculate the current SOC. As state prediction is susceptible to the offset errors of sensors, the uncertainty in measurement is captured via the error covariance matrix

$$( {s}_{θ , t ,}^{+} {s}_{x , t ,}^{+} {s}_{θ , t ,}^{-} {s}_{x , t ,}^{-} ) .$$

The terminal voltage Vₜ from observation model is calculated using the following equations 5 and 6:

$${O}_{x} ( . ) = {V}_{t} = {V}_{oc} ( {SOC}_{t} ) - {V}_{RC {1}_{t}} - {V}_{RC {2}_{t}} - {I}_{t} {R}_{s} \qquad ( 5 )$$

$${O}_{θ} ( . ) = {V}_{t} = OCV - {V}_{RC {1}_{t}} - {V}_{RC {2}_{t}} - {I}_{t} {R}_{s} \qquad ( 6 )$$

During state measurement update, the OCV is a function of SOC in the state observation model Oₓ. Similarly, during parameter measurement update, the OCV is computed from the updated sigma points (Θ) of parameters (θ) in the parameter observation model O_{θ} as in equation 6. The parameter matrix θ along with OCV is updated according to a linear state transition model with a small perturbation error during the transition from time step t to t+1.

$$θ = {[ {R}_{s} {R}_{1} {τ}_{1} {R}_{2} {τ}_{2} OCV ]}^{T} \qquad ( 7 )$$

In D-SRUKF {Wi} represents a set of scalar weights

$${W}_{0}^{m} , {W}_{0}^{c} , {W}_{i}^{m} \& {W}_{i}^{c}$$

$$( {W}_{0}^{m} = λ \frac{1}{L + λ} , {W}_{0}^{c} = {W}_{0}^{m} + ( 1 - {α}^{2} + β ) , \\ {W}_{i}^{m} = {W}_{i}^{c} = 1 / \{ 2 ( L + λ ) \} I = 1 , … , 2 L ) ,$$

where L is state or parameter dimension, λ=α2(L+κ)−L, γ=\sqrt{L+λ}.

### Initialization of States and Parameters

$$\text{?} = E [ {θ}_{0} ] , {s}_{θ , 0}^{+} = chol ( E [ ( θ - \text{?} ) {( θ - \text{?} )}^{T} ] )$$

$$\text{?} = E [ {x}_{0} ] , {s}_{x , 0}^{+} = chol ( E [ ( x - \text{?} ) {( x - \text{?} )}^{T} ] )$$

### Time Update for Parameters

$$\text{?} = \text{?} , {s}_{θ , t}^{+} = {λ}_{RLS}^{- 0.5} {s}_{θ , t - 1}^{+}$$

### Time Update for States

$${χ}_{t - 1} = [ \text{?} + γ {s}_{x , t - 1}^{+} \text{?} - γ {s}_{x , t - 1}^{+} ]$$

$${χ}_{t \vert t - 1 = P ( {χ}_{t - 1} , {θ}_{t}^{-} , {u}_{t - 1} )}^{*}$$

$$\text{?} = {\sum }_{i = 0}^{2 L} {W}_{i}^{m} {χ}_{i , t \vert t - 1}^{*}$$

$${s}_{x , t}^{-} = QRD [ \sqrt{{W}_{1 : 2 L}^{c}} ( {χ}_{1 : 2 L , t \vert t - 1}^{*} - {\hat{x}}_{t}^{-} ) ] + chol ( {Q}_{t}^{x} )$$

$${s}_{x , t}^{-} = cholupdate [ {s}_{x , t}^{-} , ( {χ}_{0 , t \vert t - 1}^{*} - {\hat{x}}_{t}^{-} ) , {W}_{0}^{c} ]$$

### Measurement Update for Parameters

$${Θ}_{t \vert t - 1} = [ {θ}_{t - 1}^{+} {θ}_{t - 1}^{+} + γ {s}_{0 , t - 1}^{+} {θ}_{t - 1}^{+} - γ {s}_{0 , t - 1}^{+} ]$$

$${Δ}_{t \vert t - 1} = {O}_{θ} ( {x}_{t}^{-} , {Θ}_{t \vert t - 1} , {u}_{t} )$$

$$\text{?} = {\sum }_{i = 0}^{2 L} {W}_{i}^{m} {Δ}_{i . t \vert t - 1}$$

$${s}_{d , t} = QRD [ \sqrt{{W}_{1 : 2 L}^{c}} ( {Δ}_{1 : 2 L , t} - {\hat{d}}_{\overline{t}} ) ] + chol ( {R}_{t}^{θ} )$$

$${s}_{d , t} = cholupdate [ {s}_{d , t} , ( {Δ}_{0 , t} - {\hat{d}}_{\overline{t}} ) , {W}_{0}^{c} ]$$

$${P}_{{θ}_{t} {d}_{t}} = {\sum }_{i = 0}^{2 L} {{W}_{i}^{c} [ {Θ}_{i , t \vert t - 1} - {\hat{θ}}_{\overline{t}} ] [ {Δ}_{i , t \vert t - 1} - {\hat{d}}_{t} ]}^{T}$$

$${K}_{t , θ} = ( {P}_{{θ}_{t} , {d}_{t}} / {s}_{d , t}^{T} ) / {s}_{d , t}$$

$$\text{?} = \text{?} + {K}_{t , θ} ( {V}_{t} - {d}_{t} )$$

$${U}_{θ , t} = {K}_{t , θ} {s}_{d , t}$$

$${s}_{θ , t}^{+} = cholupdate [ {s}_{θ , t}^{-} , {U}_{θ , t} , - 1 ]$$

### Measurement Update for States

$${χ}_{t - 1} = [ \text{?} + γ {s}_{x , t}^{-} \text{?} - γ {s}_{x , t}^{-} ]$$

$${Y}_{t \vert t - 1} = {O}_{x} ( {χ}_{t \vert t - 1} , \text{?} , {u}_{t} )$$

$${\hat{y}}_{t} = {\sum }_{i = 0}^{2 L} {W}_{i}^{m} {Y}_{i , t \vert t - 1}$$

$${s}_{y , t} = QRD [ \sqrt{{W}_{1 : 2 L}^{c}} ( {Y}_{1 : 2 L , t} - \text{?} ) ] + chol ( {R}_{t}^{x} )$$

$${s}_{y , t} = cholupdate [ {s}_{y , t} , ( {Y}_{0 , t} - {\hat{y}}_{t}^{-} ) , {W}_{0}^{c} ]$$

$${P}_{{x}_{t} {y}_{t}} = {\sum }_{i = 0}^{2 L} {{W}_{i}^{c} [ {χ}_{i , t \vert t - 1} - {\hat{x}}_{t}^{-} ] [ {Y}_{i , t \vert t - 1} - {\hat{y}}_{t}^{-} ]}^{T}$$

$${K}_{t , x} = ( {P}_{{x}_{t} , {y}_{t}} / {s}_{y , t}^{T} ) / {s}_{y , t}$$

$$\text{?} = \text{?} + {K}_{tx} ( {V}_{t} - {y}_{t} )$$

$${U}_{x , t} = {K}_{t , x} {s}_{y , t}$$

$${s}_{x , t}^{+} = cholupdate [ {s}_{x , t}^{-} , {U}_{x , t} , - 1 ]$$

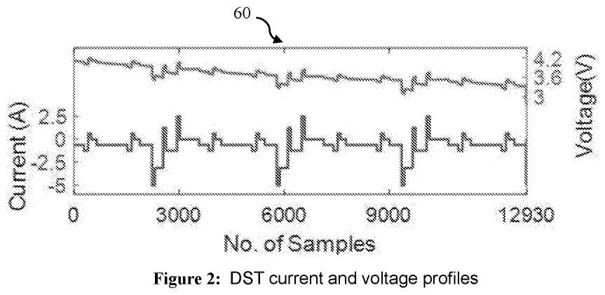

Referring now to FIG. 2, illustrates Dynamic Stress Test (DST) (60) current profile and voltage profile, in accordance with an embodiment of the present invention. The SOH of a new battery is considered to be 100%, and its capacity fades with the number of charge-discharge cycles. In the co-estimation technique, the OCV is estimated as an additional parameter. Using OCV in the observation function Oθ, OCV estimated is adapted to aging. Considering SOC-OCV LUT for 100% SOH, estimated OCV of two different times ta and tb gives SOC difference for a new battery. The ratio of accumulated charge during this period to the SOC difference for newer batteries offers the current capacity Qn at nth cycle as denoted in equation 8. Then SOH is calculated using equation 9.

$${Q}_{n} = \frac{Δ Ah}{Δ SOC} = \frac{{\int }_{{t}_{b}}^{{t}_{a}} idt}{SOC ( {t}_{a} ) - SOC ( {t}_{b} )} \qquad ( 8 )$$

$${SOH}_{n} = \frac{{Q}_{n}}{{Q}_{nom}} \times 100 \qquad ( 9 )$$

At any instant, if the power demand exceeds the threshold value, the safety mechanism of the BMS needs to be activated. Therefore, accurate estimation of SOP is a requisite. The maximum deliverable power is computed from maximum charging (I^{cha}) and discharging (I^{discha}) current, maximum allowable voltage Vₘₐₓ and updated OCV is V_{oc}. Here, R_{eq} is sum of Rₛ, R₁ and R₂ obtained from the parameter filter.

In an exemplary embodiment, for testing and validation, a Samsung ICR18650-26J 2.6 Ah Li-ion cell has been used as the test sample. Static Capacity Test (SCT), Incremental SOC-OCV test, and Dynamic Stress Tests (DST) have been performed using the Arbin Battery cycler (BTS2000). SOC-OCV relation is established using the incremental OCV test. The RC parameters are extracted by minimizing the sum squared error using the MATLAB parameter estimation toolbox.

For SOC estimation, the fully charged battery with 92% SOH was discharged with the DST test profile shown in FIG. 2. The reference SOC is calculated using the widely used coulomb counting method, and the reference OCV is then extrapolated using the OCV vs. SOC distribution. The accuracy of the proposed D-SRUKF co-estimation is compared with the state-of-the-art EKF-RLS co-estimation, and the D-SRUKF based SOC computed without co-estimation, simulated in MATLAB.

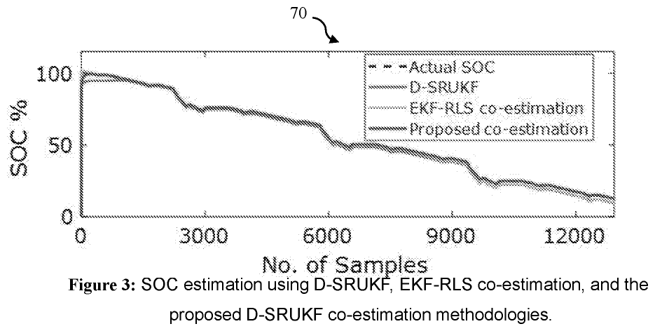

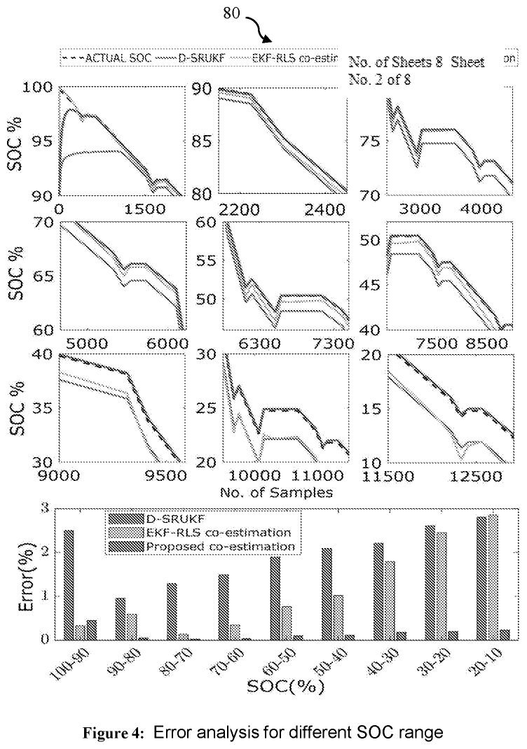

Referring now to FIG. 3, illustrates a comparison (70) of State of Charge (SOC) of a battery between different methodologies and FIG. 4 illustrates error analysis for different SOC ranges, in accordance with an embodiment of the present invention. Here, SOC estimation without co-estimation diverged from actual SOC since capacity degradation is not considered. The SOC estimated using the EKF-RLS algorithm also diverges from actual SOC in 50-0% SOC range (FIG. 4) because the EKF is accurate up to first-order only due to linearization and truncation during Jacobian computation. The proposed D-SRUKF co-estimation follows the reference SOC with a maximum error of 0.5% at 100-90% SOC range, and the error is less than 0.4% for 90-0% SOC range. The mean absolute error for SOC estimation is presented in Table 1. The results show that D-SRUKF co-estimated SOC offers the least error, with 77.60% improved accuracy over D-SRUKF estimated SOC and 58.02% over EKF-RLS co-estimation.

For SOH validation, charge-discharge cycles were performed on the battery under test. Considering the time at the start of charging ta and time at the end of charging tb, the battery capacity Qₙ is updated for every interval. Since the capacity does not change significantly for every consecutive cycle. Therefore, capacity estimated at every 10th cycle was performed, and results are presented in Table. 2. The nominal capacity of the cell is 2.6.

TABLE 1
Performance analysis of the proposed co-estimation
technique for SOC estimation is listed below:

| | Mean |
|---|---|
| Technique | Absolute Error |
| D-SRUKF | 1.8016 |
| EKF-RLS co-estimation | 0.9625 |
| D-SRUKF co-estimation | 0.404 |

TABLE 2
Error analysis for capacity estimation is listed below:

| | | EKF-RLS | | Proposed | |
|---|---|---|---|---|---|
| Cycle | Actual Capacity | estimation | Error | technique | Error |
| no. | (Ah) | (Ah) | (%) | (Ah) | (%) |
| 1 | 2.560 | 2.578 | 0.711 | 2.598 | 1.463 |
| 10 | 2.498 | 2.511 | 0.460 | 2.516 | 0.481 |
| 20 | 2.478 | 2.496 | 0.726 | 2.489 | 0.464 |
| 30 | 2.473 | 2.476 | 0.097 | 2.473 | 0.024 |
| 40 | 2.472 | 2.462 | 0.428 | 2.472 | 0.023 |
| 50 | 2.465 | 2.446 | 0.799 | 2.459 | 0.244 |

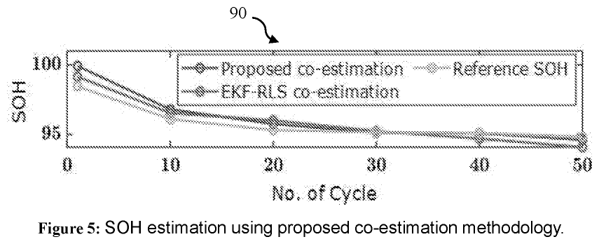

SOH estimation using EKF-RLS and the proposed technique are presented in FIG. 5 (90). The results show that the estimated SOH with the proposed co-estimation converges to the reference SOH after 50 cycles with an average error of 0.44%. In contrast, the SOH estimated with EKF-RLS co-estimation has an average error of 0.53% with 50 cycles. The error in first capacity estimation using proposed co-estimation is more than 1% due to initialization error which gradually decreases and consistently below 0.5%.

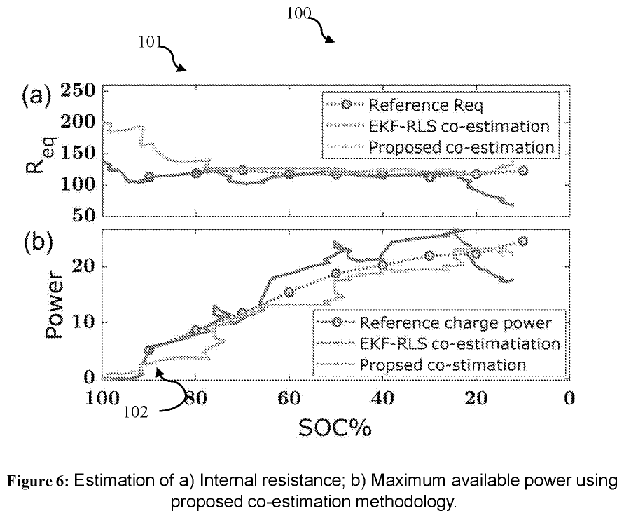

Referring now to FIG. 6A illustrates a comparison of internal resistance (101) and FIG. 6B illustrates a comparison of maximum available power (102), in accordance with an embodiment of the present invention.

FIG. 6A (101) provides the internal resistance R_{eq} (mili ohm) estimation for DST profile using the EKF-RLS co-estimation and proposed technique. EKF-RLS co-estimated R_{eq} diverges after 20% SOC but estimated R_{eq} from the proposed co-estimation follows reference as the battery discharges.

Finally, the maximum charge and discharge currents are calculated using updated parameter filter values as shown in equations 10-13. The maximum deliverable power estimated using EKF-RLS and proposed co-estimation is presented in FIG. 6B (102). It can be observed that the power estimated through EKF-RLS technique diverges from reference power, proving the proposed technique to be more accurate.

$${I}_{max}^{cha} = \frac{{V}_{max} - {V}_{oc}}{{R}_{eq}} \qquad ( 10 )$$

$${I}_{max}^{discha} = \frac{{V}_{oc} - {V}_{max}}{{R}_{eq}} \qquad ( 11 )$$

$${P}_{max}^{cha} = {I}_{max}^{cha} \times {V}_{max} \qquad ( 12 )$$

$${P}_{max}^{discha} = {I}_{max}^{discha} \times {V}_{max} \qquad ( 13 )$$

One of the technical advantages of the proposed invention provides a highly accurate estimation of battery states compared to the state-of-the-art techniques of separate state estimation. The square root formulation of the pro-posed estimator guarantees the positive semi-definite nature of the underlying state covariance matrix, improving the stability of the highly non-linear system such as battery monitoring unit. Further, Co-estimation of the three states (SOC, SOH, and SOP) improves the accuracy of the system by updating capacity and model parameters throughout the lifetime of the battery. Battery state co-estimation technique using the state-of-the-art EKF-RLS and the proposed D-SRUKF, both have complexity of O(L²) for state-parameter estimation. Therefore, D-SRUKF offers accurate and stable state estimation without adding to the computational complexity of state-of-the-art technique. This technique can be applied to different cell chemistry since it considers the electrical equivalent model of batteries which is independent of electro-chemical parameters of other battery chemistries.

1. A method of estimating battery states, the method comprising:
creating an enhanced 2-RC circuit battery model as the electrical equivalent circuit of a battery, wherein the model accounts for nonlinear polarization effects and dynamic parameter adaptation;
performing an incremental open circuit voltage (OCV) test to extract a plurality of 2-RC model parameters, wherein the parameters include internal resistance, temperature, OCV, and time-dependent voltage relaxation characteristics;
estimating a State of Charge (SOC) of the battery using a modified Dual Square Root Unscented Kalman Filter (D-SRUKF) based on a multi-factor co-estimation technique that simultaneously refines model parameters using a covariance-matching algorithm;
estimating a State of Health (SOH) of the battery based on a real-time adaptive degradation model, incorporating SOC, OCV, and historical cycle degradation trends of the 2-RC circuit battery model;
estimating a State of Power (SOP) of the battery based on dynamic real-time power constraints, maximum deliverable power, maximum allowable voltage, the internal resistance, and the OCV, wherein the SOP estimation compensates for transient voltage recovery effects and load-dependent resistance variations.

2. The method as claimed in claim 1, wherein the 2-RC circuit battery model comprises two non-observable states comprising State of Charge (SOC) and Voltage of the 2-RC circuit battery model (VRC).

3. The method as claimed in claim 1, wherein the co-estimation technique use interdependence among battery states, and wherein SOH of the battery is accounted for estimating SOC of the battery.

4. The method as claimed in claim 1, wherein the maximum deliverable power is computed based on maximum charging current and maximum discharging current.

5. The method as claimed in claim 1, wherein the maximum error in SOC estimation is 0.5% at 1.00%-90% SOC range, and wherein the error in SOC estimation is less than 0.4% at 90%-0% SOC range.

6. The method as claimed in claim 1, wherein the SOH is estimated for each charging and discharging cycle of the battery.

7. The method as claimed in claim 1, wherein the D-SRUKF have complexity of o(L²) for state parameter estimation.

8. The method as claimed in claim 1, wherein the D-SEUKF uses an observational model and a process model to describe a discrete time-invariant system.

9. The method as claimed in claim 1, wherein the SOH is estimated using
$${Q}_{n} = \frac{Δ Ah}{Δ SOC} = \frac{{\int }_{{t}_{b}}^{{t}_{a}} idt}{SOC ( {t}_{a} ) - SOC ( {t}_{b} )} and {SOH}_{n} = \frac{{Q}_{n}}{{Q}_{nom}} \times 100.$$

10. The method as claimed in claim 1, wherein the error in SOH estimation is less than 0.5%.
